(19) United States
(12) Patent Application Publication
(10) Pub. No.: US 2022/0122836 A1
(43) Pub. Date: Apr. 21, 2022

(54) METHOD FOR GROWING A NON-POLAR A-PLANE GALLIUM NITRIDE USING ALUMINUM NITRIDE / GALLIUM NITRIDE SUPERLATTICES

(71) Applicant: COLLABORATIVE RESEARCHIN ENGINEERING, SCIENCE AND TECHNOLOGY CENTER, Bayan Lepas (MY)

(72) Inventors: Anas BIN KAMARUNDZAMAN, Kuala Lumpur (MY); Ahmad Shuhaimi BIN ABU BAKAR, Kuala Lumpur (MY); Mohd Adreen Shah BIN AZMAN SHAH, Kuala Lumpur (MY); Omar Ayad Fadhil AL- ZUHAIRI, Kuala Lumpur (MY)

(21) Appl. No.: 17/422,196

(22) PCT Filed: Jan. 17, 2019
(86) PCT No.: PCT/MY2019/000003

§ 371 Date: Jul. 11, 2021

(51) Int. Cl. H01L 21/02

(52) U.S. Cl. CPC H01L 21/0254; H01L 21/02647; H01L 21/02661; H01L 21/0242

(57) ABSTRACT

A method for growing a non-polar a-plane gallium nitride includes cleaning of r-sapphire substrate, and nitridating for initiating growth sequences. The growth sequences include growing a gallium nitride nucleation layer, growing a thick first layer of gallium nitride, growing a film stack of gallium nitride and aluminum nitride as a superlattices layer, and overgrowing of gallium nitride on superlattices layer to form a second layer. The non-polar a-plane gallium nitride is grown by inserting multiple layers of a gallium nitride and an aluminum nitride for improving lateral surface morphology of gallium nitride on r-sapphire substrate.

### CROSS-REFERENCE TO RELATED APPLICATIONS

See Application Data Sheet.

### STATEMENT REGARDING FEDERALLY SPONSORED RESEARCH OR DEVELOPMENT

Not applicable.

### THE NAMES OF PARTIES TO A JOINT RESEARCH AGREEMENT

Not applicable.

### INCORPORATION-BY-REFERENCE OF MATERIAL SUBMITTED ON A COMPACT DISC OR AS A TEXT FILE VIA THE OFFICE ELECTRONIC FILING SYSTEM (EFS-WEB)

Not applicable.

### STATEMENT REGARDING PRIOR DISCLOSURES BY THE INVENTOR OR A JOINT INVENTOR

Not applicable.

### BACKGROUND OF THE INVENTION

### 1. Field of the Invention

Embodiments of the present invention relate to a method of growing a thin film gallium nitride on an r-plane sapphire substrate using aluminum nitride/gallium nitride superlattices, in particular relates to growing on non-polar sapphire plane through metal-organic chemical vapour deposition (MOCVD) method.

### 2. Description of Related Art Including Information Disclosed Under 37 CFR 1.97 and 37 CFR 1.98

Currently in all nitride-based devices one or more heterostructures are grown along the polar plane in e-direction resulting in formation of strong electrostatic fields growing in parallel direction. Particularly, the electrostatic fields are created by fixed sheet charges associated with polarization and discontinuities at surfaces by interfaces within c-plane of nitride structures.

Recently, polarization in III-nitride compounds has attracted increased attention due to the large effect polarization-induced electric fields. Particularly, induced electric fields have hetero structures employed in nitride-based optoelectronic and electronic devices. Moreover, the nitride-based optoelectronic devices and electronic devices are also subjected to experience polarization-induced effects. Furthermore, the polarization-induced effect utilizes nitride films grown in the polar c-direction.

Subsequently, spontaneous and piezoelectric polarizations of nitride films are aligned along the polarization axis.

Conventionally, total polarization of a nitride film depends on the composition and strain state. Discontinuities of the total polarization exist at interfaces between the layers of adjacent device. Particularly, nitride films are associated with fixed sheet charges giving rise to internal electric fields.

With developments, lot of techniques has been employed in the growth of gallium nitride in order to achieve low defect densities and improve the crystalline quality. Particularly, the development of the growth of gallium nitride includes the steps of growing highly planar non-polar a-plane gallium nitride films by hydride vapor phase epitaxy (HVPE) and subsequently dislocations in gallium nitride are threaded. Subsequently, a non-polar (1120) a-plane gallium nitride (gallium nitride) films with planar surfaces are grown on (1102) r-plane sapphire substrates by employing a low temperature nucleation layer as a buffer layer.

The application WO/2003/089695 published on 30 Oct. 2003 focuses only on growing films exhibiting improved surface and structural quality as of gallium nitride on r-plane sapphire via MOCVD. However, it has various disadvantages for polarization-induced electric fields in a two-dimensional electron gas (2DEG) formation in nitride-based transistor structures. Moreover, the polarization-induced electric fields have spatially separated electrons and hole wave functions in quantum well (QW) structures.

The application US20060008941 published on Dec. 1, 2006 discloses a method suitable for high-quality thick films of a-plane gallium nitride.

Particularly, restricting the use of thick films, as substrates in homoepitaxial device layer leads to re-growth. Moreover, it limits to the methods for growing highly planar, specular a-plane gallium nitride films.

The application U.S. Pat. No. 6,900,070 published on 31 May 2005 describes about LEO methods for a-gallium nitride films to achieve threading dislocation reduction. Moreover, low dislocation density a-GaN can be used as a buffer layer for high performance polarization-induced field free (Al,B,In,Ga) N-based devices. However, it does not provide high symmetry a-GaN surface exhibiting LEO stripe morphologies that were dependent on crystallographic stripe alignment

Particularly, non-polar a-gallium nitride gaining a major attention due to position of its crystal structure that allowed high internal quantum efficiency without facing the quantum-confined Stark effect (QCSE). However, non-polar a-gallium nitride has a different growth condition as c-plane gallium nitride due to its crystalline orientations. Growing non-polar gallium nitride on sapphire would be very challenging as the a-gallium nitride and r-sapphire have two sides of lattice mismatch to be taken in consideration which is along [0001] and [1-100]. Moreover, lattice mismatch generally contributes to a poor morphology with surface striations, faceted pits, and a defective microstructure, including basal-plane stacking faults (BSFs) bounded by partial dislocations (PDs). This explained the cause of gallium nitride growth on a foreign substrate suffering from high densities of stacking faults (10⁵-10⁶ cm⁻³) and threading dislocations (10⁸-10¹⁰ cm⁻³).

Currently in the prior art, there is no existing method which is able to grow films that exhibits improved surface and structural quality for growing gallium nitride on r-plane. Thus, the present invention focuses on method on growing multi layers of gallium nitride and aluminium nitride as superlattices for improving lateral surface morphology of a gallium nitride on r-sapphire. Moreover, there is also a need of a method for improving the crystalline quality in non-polar growth without involving any foreign materials for growth interruption or substrate patterning.

### BRIEF SUMMARY OF THE INVENTION

Various embodiments of present invention disclose a method for growing non-polar a-plane gallium nitride. Particularly, the method includes cleaning of one or more r-sapphire substrates to remove contamination from the r-sapphire substrates. Particularly, hydrogen gas cleans one or more r-sapphire substrates at a temperature of about 1120° C. Subsequently, multiple precursors used in the gallium nitride and aluminum nitride growth include trimethyl-gallium (TMGa) for gallium, trimethyl-aluminium (TMAl) for aluminium and ammonia (NH₃) for nitrogen. The carrier gas is hydrogen gas. Furthermore, the growing step further includes nitridation to initiate growth sequence. Particularly, nitridation is performed at a temperature of about 1030° C. for about 30 minutes. Subsequently, a thin first layer of gallium nitride is grown at a low temperature to form a gallium nitride nucleation layer followed by thick first layer of gallium nitride. Moreover, the thickness of first thick layer of gallium nitride is about 500 nanometer (nm) to about 1 micrometer (mm) in thickness. Furthermore, the film stack of gallium nitride and aluminum nitride is grown as super-lattices layer. Moreover, the gallium nitride is also overgrown on the superlattices layer to form a second layer. Furthermore, the thickness of second layer is about less than 1 micrometer (mm) or equal to 1 micrometer (mm) or more than 1 micrometer (mm).

Various embodiments of the present invention relate to growing of gallium nitride on non-polar a-plane by inserting multiple layers of gallium nitride and aluminum nitride. In one embodiment, insertion of multi-layer stacks improves lateral surface morphology of gallium nitride on one or more r-sapphire substrates.

In another embodiment, insertion of super-lattices stacks improves lateral surface morphology of gallium nitride on one or more r-sapphire substrates.

Particularly, gallium nitride nucleation layer has a thickness of 90 nanometer (nm), Furthermore, gallium nitride nucleation layer is grown directly on the r-sapphire substrate at a low temperature of about 500° C. Subsequently the 1 um thick layer of gallium nitride is grown on the gallium nitride nucleation layer. Subsequently, the aluminum nitride/gallium nitride super-lattices layer is grown in between 1 mm of undoped gallium nitride. Henceforth, the gallium nitride continues to grow for about one micrometer (mm) after the superlattices layer is grown. Particularly, the nucleation layer is a gallium nitride layer and the growing layer is a-plane gallium nitride layer. Furthermore, the nucleation layer is maintained at a temperature of about 500° C. Subsequently the temperature is increased to 1030° C. to grow the first thick layer of gallium nitride. Subsequently, the multi-layer stacks and superlattices stacks includes anyone of 30 pairs and 40 pairs of gallium nitride and aluminum nitride to form the superlattices layer. Particularly, the multi-layer stack grows at a temperature of about 1030° C. Moreover, the multi-layer stack is having a thickness in a ratio of about 5 nanometer (nm) of aluminum nitride to 20 nanometer (nm) of gallium nitride. Furthermore, gallium nitride is overgrown on superlattices layer at a temperature of about 1030° C. to form a second thick layer. Also, one micrometer thick layer of the gallium nitride is grown at a temperature of about 1030° C. Thus, the growing step further includes cooling the non-polar a-plane gallium nitride under nitrogen ambient pressure.

Various embodiments of present invention also disclose various planes for growing r-sapphire substrates. Particularly, the r-sapphire substrates have a plane orientation of r-plane (1-102). Moreover, the plane orientation is selected anyone from a two dimensional growth plane and a three dimensional growth plane. Moreover, the r-sapphire substrate is any one selected from silicon carbide, gallium nitride, silicon, zinc oxide, boron nitride, lithium aluminate, lithium niobate, germanium, aluminum nitride, and lithium gallate. Subsequently, threading dislocation (TD) propagates from an interface of gallium nitride and multiple r-sapphire substrates propagate along a plane [11-20] gallium nitride. Particularly, the threading dislocation (TD) propagation along [11-20] gallium nitride block interface of aluminum nitride and gallium nitride.

The method performs insertion of aluminum nitride and gallium nitride through metal-organic chemical vapour deposition (MOCVD). Particularly, the metal-organic chemical vapour deposition (MOCVD) is a horizontal metal-organic chemical vapour deposition (MOCVD) system. Moreover, lateral surface morphology of the gallium nitride on one or more r-sapphire substrates is performed by analyzing the low defect densities to improve crystalline quality.

### BRIEF DESCRIPTION OF THE SEVERAL VIEWS OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is flowchart illustrating a method to grow a non-polar a-plane gallium nitride for improving lateral surface morphology of gallium nitride on r-sapphire substrate in accordance with one or more embodiments of the present invention.

FIG. 2A is a pictorial snapshot illustrating TEM images for aluminium nitride/gallium nitride superlattices cross-sectional view in accordance with one embodiment of the present invention.

FIG. 2B is a pictorial snapshot illustrating TEM images for aluminium nitride/gallium nitride superlattices cross-sectional view in accordance with another embodiment of the present invention.

FIG. 3A is a pictorial graphical snapshot illustrating a 2-theta scan phase analysis for a-gallium nitride with the insertion of 40 pairs superlattices in accordance with one or more embodiments of present invention.

FIG. 3B is a pictorial graphical snapshot illustrating an omega-2 Theta scan analysis for a-gallium nitride with the insertion of 40 pairs in a superlattices layer in accordance with one or more embodiments of present invention.

FIG. 4 is a pictorial representation illustrating a three dimensional surface of nucleation layer grown at low temperature in accordance with one or more embodiments of present invention.

FIG. 5 is a pictorial representation illustrating structure of a-gallium nitride with the insertion of aluminium nitride/gallium nitride superlattices in accordance with one or more embodiments of present invention.

FIG. 6 is a schematic pictorial representation illustrating a growth sequence for a-gallium nitride with aluminium nitride/gallium nitride superlattices.

While the present method of growing a non-polar a-plane gallium nitride has been described herein by way of example for several embodiments and illustrative drawings, those skilled in the art will recognize that the present growing method is not limited to embodiments or drawings described. It should be understood that the drawings and detailed description thereto are not intended to limit embodiments to the particular form disclosed, Rather, the intention is to cover all modifications, equivalents and alternatives falling within the spirit and scope of the invention as defined by the appended claims.

Any headings used herein are for organizational purposes only and are not meant to limit the scope of the description or the claims. As used herein, the word “can” and “may” is used in a permissive sense (i.e., meaning having the potential to), rather than the mandatory sense (i.e., meaning must). Similarly, the words “include”, “including”, and “includes” mean including, but not limited to.

### DETAILED DESCRIPTION OF THE INVENTION

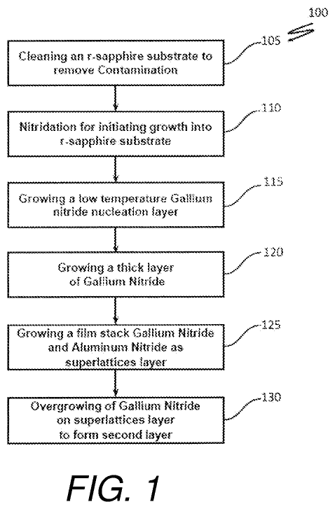

Various embodiments of the present invention relates to method for growing a non-polar a-plane gallium nitride by inserting multiple layers of gallium nitride and aluminium nitride to improve surface morphology. Moreover, the principles of the present invention and their advantages are best understood by referring to FIG. 1 to FIG. 6. In the following detailed description of Illustrative or exemplary embodiments of the disclosure, specific embodiments in which the disclosure may be practiced are described in sufficient detail to enable those skilled in the art to practice the disclosed embodiments. For example, specific details such as specific method steps, structures, elements, and connections are presented herein. However, it is to be understood that the specific details presented need not be utilized to practice the embodiments of the present disclosure. The following detailed description is, therefore, not to be taken in a limiting sense, and the scope of the present disclosure is defined by the appended claims and equivalents thereof.

References within the specification to “one embodiment,” “an embodiment,” “embodiments,” or “one or more embodiments” are intended to indicate that a particular feature, structure, or characteristic described in connection with the embodiment is included in at least one embodiment of the present disclosure. The appearance of such phrases in various places within the specification are not necessarily all referring to the same embodiment, nor are separate or alternative embodiments mutually exclusive of other embodiments. Further, various features are described which may be exhibited by some embodiments and not by others. Similarly, various requirements are described which may be requirements for some embodiments but not other embodiments.

FIG. 1 is flowchart illustrating a method 100 to grow a non-polar α-plane gallium nitride for improving lateral surface morphology of gallium nitride on r-sapphire substrate in accordance with one or more embodiments of the present invention. Particularly, the method 100 starts at step 105 and proceeds to step 110. At step 105, one or more r-sapphire substrates are cleaned to remove contamination from the r-sapphire substrates.

Particularly, hydrogen gas cleans one or more r-sapphire substrates.

Moreover, hydrogen cleans at a temperature of about 1120° C.

The step 105 of method 100 proceeds to step 110. At step 110, nitridation is performed to initiate growth sequence. In particular, the growth sequence is initiated by diffusing one or more layers of nitrogen gas into the r-sapphire substrate. Moreover, nitridation is performed at a temperature of about 1030° C. for about 30 minutes. Furthermore, the nitridation process using ammonia and hydrogen. The step 110 of method 100 proceeds to 115. At step 115, gallium nitride nucleation layer is grown on one or more r-sapphire substrate. Particularly, the gallium nitride nucleation layer is grown at a low temperature of about 500° C. The thickness of gallium nitride nucleation layer is 90 nm. In Use, the gallium precursor is trimethyl gallium and the nitrogen precursor is ammonia. Hydrogen acts as the carrier gas. The step 115 of method 100 proceeds to step 120. At step 120, a thick first layer of gallium nitride is grown on top of the gallium nitride nucleation layer. Particularly, the thick first layer is a gallium nitride layer. Moreover, thickness of first layer of gallium nitride is about 500 nanometer (nm) to about 1 micrometer (mm) in thickness. Furthermore, growing of gallium nitride is performed at a temperature of about 1030° C.

The step 120 proceeds of method 100 to step 125. At step 125, one or more film stacks of gallium nitride and aluminum nitride are grown as the superlattices layer. Particularly, the film stack is having anyone of 30 pairs and 40 pairs of gallium nitride and aluminum nitride to form the superlattices layer. The step 125 of method 100 proceeds to step 130. At step 130, the gallium nitride is overgrown on the superlattices layer to form a second layer. Particularly, overgrowing of gallium nitride on superlattices layer is performed at a temperature of about 1030° C. to form the second layer. Furthermore, the second layer is about one micrometer thick. The film stack and multi-layer stack are used interchangeably for convenience.

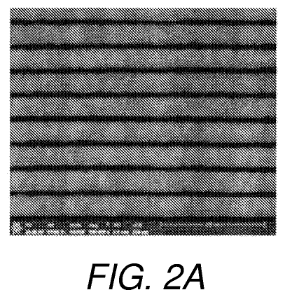

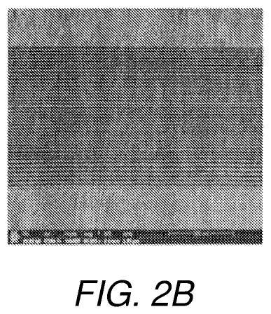

FIG. 2A and FIG. 2B are pictorial snapshots illustrating Transmission electron microscopy (TEM) images for aluminium nitride and gallium nitride superlattices cross-sectional view in accordance with one or more embodiments of the present invention. Particularly, the grown samples show lateral two dimensional (2D) growth. Moreover, the two dimension growth has a specular reflectance by the naked eye. Subsequently, the cross sectional transmission electron microscopy (TEM) images as depicted in FIG. 2A and FIG. 2B also illustrate an abrupt interface of aluminum nitride and gallium nitride thin layer in the superlattices layer region.

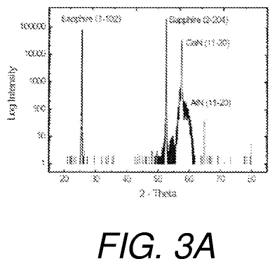

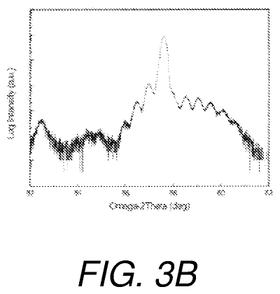

FIG. 3A is a pictorial graphical snapshot illustrating a 2-theta scan phase analysis for gallium nitride having an insertion of 40 pairs superlattices and FIG. 3B is a pictorial graphical snapshot illustrating an omega-2 theta scan analysis for a-gallium nitride having an insertion of 40 pair superlattices in accordance with one or more embodiments of present invention.

Particularly, as illustrated in FIG. 3A and FIG. 3B the phase analysis from HR-XRD 2q-w scan reveal that the surface orientation of grown gallium nitride to be a-plane (11-20) gallium nitride. Moreover, giving high reflections of sapphire [1-120], [2-240] and gallium nitride [11-20] at 25.64°, 52.68° and 57.78° respectively. Furthermore, single reflection peak of gallium nitride at 57.78° indicates that the grown gallium nitride is mono-crystalline. Henceforth, gallium nitride is oriented along the [11-20] direction. Subsequently, as based on X-ray rocking curve (XRC), the omega scan shows a significant improvement in the crystalline quality based on the reduction in FWHM between a-gallium nitride with and without the aluminum nitride/gallium nitride superlattices layer.

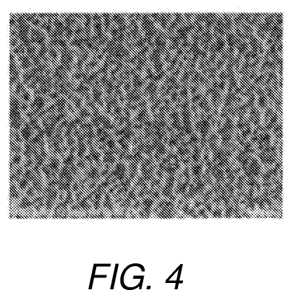

FIG. 4 is a pictorial representation illustrating a three dimensional surface of nucleation layer grown at low temperature in accordance with one or more embodiments of present invention. Particularly, the nucleation layer is a gallium nitride layer and the growing layer is α-plane gallium nitride layer. Moreover, the nucleation layer is maintained at a temperature of about 500° C. Subsequently, thick first layer of the gallium nitride is grown at 1030° C. on top of gallium nitride nucleation layer. Henceforth, the r-sapphire substrates have a plane orientation of r-plane (T-102). Moreover, the plane orientation is selected anyone from a two dimensional growth plane and a three dimensional growth plane.

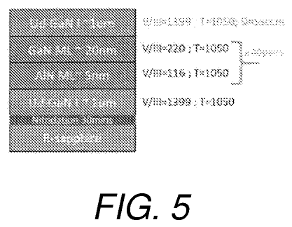

FIG. 5 is a pictorial representation illustrating structure of a-gallium nitride with the insertion of aluminium nitride/gallium nitride superlattices in accordance with one or more embodiments of present invention. Particularly, insertion of aluminum nitride and gallium nitride through metal-organic chemical vapour deposition (MOCVD). Moreover, the metal-organic chemical vapour deposition (MOCVD) is a horizontal metal-organic chemical vapour deposition (MOCVD) system.

In one embodiment, multiple samples are grown on two inch r-plane (1-102) sapphire substrates using a Taiyo Nippon Sanso SR2325KS horizontal MOCVD system.

Particularly, the growing of gallium nitride on r-sapphire substrates includes growing of gallium nitride nucleation layer at low temperature. The growth of gallium nitride nucleation layer is at the temperature of about 500° C. Moreover, the thickness of gallium nitride nucleation layer is about 90 nm, Furthermore, the first thick layer of gallium nitride is grown on the nucleation layer. The grown thick first layer is gallium nitride layer. Moreover, the thick first layer is about 500 nanometer (nm) to about 1 micrometer (μm) in thickness. Furthermore, the film stack of gallium nitride and aluminum nitride is also grown as a superlattices layer. Subsequently, the gallium nitride is overgrown on the superlattices layer to form a second layer.

Henceforth, the thickness of second layer is about less than 1 micrometer (μm) or equal to 1 micrometer (μm) or more than 1 micrometer (μm).

Furthermore, gallium nitride nucleation layer is grown directly on the r-sapphire at a low temperature of about 500° C. Subsequently, the first thick layer gallium nitride is grown on the nucleation layer. Subsequently, the superlattices layer is grown in between 1 μm undoped gallium nitride. Henceforth, gallium nitride continues to grow for about 1 micrometer (μm) after the superlattices layer is grown. Subsequently, the film stack includes anyone of 30 pairs and 40 pairs of gallium nitride and aluminum nitride to form the superlattices layer. Particularly, the film stack grows at a temperature of about 1030° C., Moreover, the film stack is having a thickness in a ratio of about 2 nanometer (nm) to about 10 nanometer (nm) of aluminum nitride to 15 nanometer (nm) to about 50 nanometer (nm) of gallium nitride. Furthermore, overgrowing of gallium nitride on the superlattices layer is performed at a temperature of about 1030° C. to form second layer. Also, one micrometer thick layer of the gallium nitride is grown at a temperature of about 1030° C. Thus, the growing step further includes cooling the non-polar α-plane gallium nitride under nitrogen pressure. The thickness of the produced gallium nitride is 90 nanometer (nm).

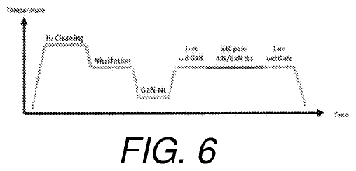

FIG. 6 is a schematic pictorial representation illustrating a growth sequence for a-gallium nitride with aluminium nitride/gallium nitride superlattices. Particularly, growing a non-polar α-plane gallium nitride includes cleaning of r-sapphire substrate to remove contamination from r-sapphire substrate. Furthermore, hydrogen gas cleans one or more r-sapphire substrates at a temperature of about 1120° C. Particularly, multiple precursors used in the growth are trimethyl-gallium (TMGa) for gallium, trimethyl-alum inium (TMAl) for aluminium and ammonia (NH₃) for nitrogen. Moreover, the carrier gas is hydrogen gas. Subsequently, nitridation process for 30 minutes and further step including growing gallium nitride nucleation layer at 500° C. on sapphire. Moreover, thick first layer of gallium nitride is grown at 1030° C. to form a gallium nitride thick first layer. Furthermore, film stack of gallium nitride and aluminum nitride is also grown as superlattices layer. Henceforth, gallium nitride on superlattices layer is overgrown to form a second layer. Also, threading dislocation (TD) propagates from an interface of the gallium nitride and multiple r-sapphire substrates propagate along a plane [11-20] gallium nitride. Particularly, the threading dislocation (TD) propagation along [11-20] gallium nitride block at the interface of aluminum nitride and gallium nitride.

In particular, the non-polar α-plane gallium nitride is grown by inserting multiple layers of gallium nitride and aluminum nitride for improving lateral surface morphology of gallium nitride on r-sapphire substrate. Moreover, multiple lateral surface morphologies of the gallium nitride on one or more r-sapphire substrates are performed by analyzing low defect densities for improving multiple crystalline qualities of the lateral surface morphology. Furthermore, the r-sapphire substrate is any one selected from silicon carbide, gallium nitride, silicon, zinc oxide, boron nitride, lithium aluminate, lithium niobate, germanium, aluminum nitride, and lithium gallate.

The present instant invention has an advantage of providing low defect densities and improves the crystalline quality by inserting aluminium nitride/gallium nitride strained layer superlattices in the growth of a-gallium nitride on r-sapphire. Moreover, it improves the crystalline quality in nonpolar growth as no foreign materials are involved in preventing growth interruption or substrate patterning. Furthermore, a huge difference in lattice mismatch enables the interfaces of gallium nitride and aluminium nitride layers to create compressive stress on a-gallium nitride film.

Subsequently, the method involved in present invention also reduces the tensile stress and strain on the interface of a-gallium nitride and r-sapphire Interface. Henceforth, resulting in a relaxation state of the grown α-plane gallium nitride.

1. A method for growing a non-polar α-plane gallium nitride, the method comprising the steps of:
cleaning a plurality of r-sapphire substrates to remove contamination from said plurality of r-sapphire substrates;
nitridating for initiating growth sequence by diffusing ammonia and hydrogen gas into said r-sapphire substrate to harden said r-sapphire substrate;
growing a thin layer of said gallium nitride at a low temperature to form a gallium nitride nucleation layer;
growing a thick first layer of gallium nitride with one um thickness on the nucleation layer;
growing a film stack of said gallium nitride and an aluminum nitride as a superlattices layer; and
overgrowing of said gallium nitride on said superlattices layer to form a second layer,
wherein said non-polar α-plane gallium nitride is grown by inserting a plurality of layers of said gallium nitride and said aluminum nitride for improving a plurality of lateral surface morphologies of said gallium nitride on said plurality of r-sapphire substrates.

2. The method as claimed in claim 1, wherein the step of nitridating is performed at a temperature of about 1030° C. for about 30 minutes.

3. The method as claimed in claim 1, wherein said gallium nitride nucleation layer is grown at 500° C. with a thickness of 90 nm.

4. The method as claimed in claim 1, wherein said thick first layer of said gallium nitride is about 500 nm to about 1 micrometer in thickness.

5. The method as claimed in claim 1, wherein said film stack is having anyone of 30 pairs and 40 pairs of said gallium nitride and said aluminum nitride to form said superlattices layer.

6. The method as claimed in claim 1, wherein said second layer is a thickness layer of about less than 1 micrometer (mm) or equal to 1 micrometer (mm) or more than 1 micrometer.

7. The method as claimed in claim 6, wherein said overgrowing of said gallium nitride on said superlattices layer is performed at a temperature of about 1030° C. to form said second layer.

8. The method as claimed in claim 1, wherein said growing step further comprises cooling said non-polar α-plane gallium nitride under nitrogen pressure.

9. The method as claimed in claim 1, wherein said growing at least one micrometer thick layer of said gallium nitride is performed at a temperature of about 1030° C.

10. The method as claimed in claim 1, wherein said nucleation layer is a gallium nitride layer.

11. The method as claimed in claim 9, wherein said thick first gallium nitride layer is maintained at a temperature of about 1030° C.

12. The method as claimed in claim 5, wherein said film stack grows at a temperature of about 1030° C.

13. The method as claimed in claim 12, wherein said film stack is having a thickness in a ratio of about 2 nanometer (nm) to about 10 nanometer (nm) of aluminum nitride to 15 nanometer (nm) to about 50 nanometer (nm) of gallium nitride.

14. The method as claimed in claim 7, wherein said superlattices layer grows in between 1 mm undoped gallium nitride and said gallium nitride continues to grow for about 1 mm after said superlattices layer.

15. The method as claimed in claim 1, wherein said r-sapphire substrate has a plane orientation of r-plane (1-102).

16. The method as claimed in claim 15, wherein said plane orientation is comprised of one of a group consisting of a two dimensional growth plane and a three dimensional growth plane.

17. The method as claimed in claim 1, wherein said method performs said insertion step of said aluminum nitride and said gallium nitride through metal-organic chemical vapour deposition (MOCVD) and wherein said metal-organic chemical vapour deposition (MOCVD) is a horizontal metal-organic chemical vapour deposition (MOCVD) system.

18. The method as claimed in claim 1, wherein said plurality of precursors is selected from trimethyl-gallium (TMGa), trimethyl-aluminium (TMAl) and ammonia (NH3).

19. The method as claimed in claim 1, wherein said carrier gas is hydrogen gas and wherein said hydrogen gas cleans said r-sapphire substrate at a temperature of about 1120° C.

20. The method as claimed in claim 1, wherein said growing layer is an “α-plane” gallium nitride layer,

21. The method as claimed in claim 1, wherein said gallium nitride nucleation layer has a thickness of 90 nanometer (nm) and said gallium nitride is grown directly on said r-sapphire at a low temperature of about 500° C.

22. The method as claimed in claim 1, wherein said r-sapphire substrate is comprised of one of a group consisting of: silicon carbide, gallium nitride, silicon, zinc oxide, boron nitride, lithium aluminate, lithium niobate, germanium, aluminum nitride, and lithium gallate.

23. The method as claimed in claim 1, wherein said plurality of lateral surface morphologies of said gallium nitride on said plurality of r-sapphire substrates is performed by analyzing a plurality of low defect density for improving a plurality of crystalline quality of said lateral surface morphology.

24. The method as claimed in claim 1, wherein threading dislocation (TD) propagates from an interface of said gallium nitride and said plurality of r-sapphire substrates propagates along a plane [11-20] gallium nitride.

25. The method as claimed in claim 24, wherein said threading dislocation (TD) propagation along [11-20] gallium nitride block interface of aluminum nitride and gallium nitride.
